(19) United States
(12) Patent Application Publication
(10) Pub. No.: US 2007/0080465 A1
(43) Pub. Date: Apr. 12, 2007

(54) Printed board, electronic board and electronic device

(75) Inventor: Hideo Ebukuro, Saitama (JP)

Correspondence Address: OLIFF & BERRIDGE, PLC, P.O. BOX 19928, ALEXANDRIA, VA, 22320, US

(73) Assignee: Fuji Xerox Co., Ltd., Tokyo (JP)

(21) Appl. No.: 11/396,605

(22) Filed: Apr. 4, 2006

(30) Foreign Application Priority Data
Aug. 26, 2005 (JP) 2005-246069

(51) Int. Cl. H01L 23/48

(52) U.S. Cl. 257/774

(57) ABSTRACT

A printed board having wiring patterns laminated with insulating layers therebetween is provided. The printed board has a through hole and via holes. A terminal of an electronic component can be inserted into the through hole and a conducting layer is formed on the through hole for connecting wiring patterns of outer layers. A wiring pattern of an inner layer is not connected electrically to the conducting layer. The via holes are provided around the through hole for electrically connecting the wiring pattern of the inner layer and the wiring patterns of the outer layers.

### CROSS-REFERENCE TO RELATED APPLICATION

This application claims priority under 35 USC 119 from Japanese Patent Application No. 2005-246069, the disclosure of which is incorporated by reference herein.

### BACKGROUND

### Technical Field

The present invention relates to a printed board having wiring patterns formed thereon, an electronic board using this printed board and an electronic device on which the electronic board is loaded.

A connector is mounted on the electronic board and is connected to another connector from the outside so that it is possible to transmit a signal to the outside (another printed board or other components mounted on the printed board) and to receive a signal from the outside.

A connector pin of the connector is inserted into a through hole formed on the printed board and soldered on the back surface of the printed board (surface opposite to the connector-mounted side surface) so that it is mounted on the printed board and connected to the wiring patterns formed on the printed board.

In a multilayer printed board having wiring patterns laminated, the wiring patterns are electrically connected by a conducting layer formed on the inner wall of the through hole. When the connector pin of the connector is inserted into the conducting layer of the through hole to be soldered, to which the plural wiring patterns are connected, a wiring pattern of each of the layers serves as a heat dissipating fin. Heat applied to the connector pin is dissipated from the wiring patterns to the insulating layer between the wiring patterns. This causes a problem such that the connector pin of the connector is not adequately soldered to the multilayer printed board.

Further, in these days, there is used Pb-free soldering which does not use lead. Since Pb-free soldering presents a high melting point, there is a need to heat the terminal of the connector sufficiently. For this reason, if heat applied to the terminal is dissipated from the wiring pattern, there may occur poor soldering.

### SUMMARY

An aspect of the present invention is a printed board having wiring patterns laminated with insulating layers therebetween, including: a through hole into which a terminal of an electronic component can be inserted and at which a conducting layer for connecting wiring patterns of outer layers is formed; a wiring pattern of an inner layer which is not connected electrically to the conducting layer; and via holes, provided around the through hole, for connecting the wiring pattern of the inner layer and the wiring patterns of the outer layers electrically.

### BRIEF DESCRIPTION OF THE DRAWINGS

Embodiments of the present invention will be described in detail based on the following figures, wherein:

FIGS. 1A and 1B are an elevational view and a side cross-sectional view, respectively, illustrating a printed board according to a first embodiment of the present invention;

FIG. 2 is a side cross-sectional view of the printed board according to the first embodiment of the present invention, on which a connector is mounted;

FIG. 3 is a side cross-sectional view of a printed board according to another embodiment of the present invention, on which a connector is mounted;

FIG. 4 is a side cross-sectional view according to another embodiment of the present invention;

FIG. 5 is a perspective view illustrating a part of a pattern of a printed board according to another embodiment of the present invention; and

FIG. 6 is a side cross-sectional view of a printed board of related art.

### DETAILED DESCRIPTION

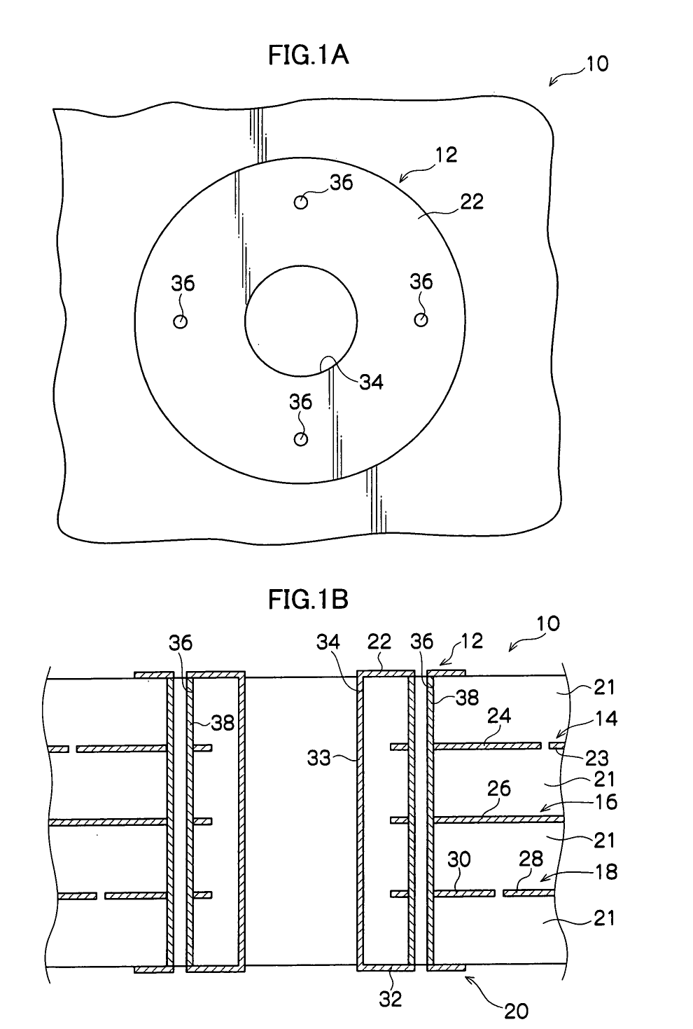

A multilayer printed board 10, which is a printed board according to an embodiment of the present invention will be described based on FIG. 1.

FIGS. 1A and 1B illustrate an elevational view and a side cross-sectional view of the multilayer printed board 10.

As shown in FIG. 1B, the multilayer printed board 10 is a board having a multilayer configuration of five layers in which a first signal wiring layer 12, a second signal wiring layer 14, a ground layer 16, a power layer 18 and a third signal wiring layer 20 are laminated via insulating layers 21. The first signal wiring layer 12, the second signal wiring layer 14, the ground layer 16, the power layer 18 and the third signal wiring layer 20 are made of copper that is metallic conductor.

Ground patterns 22 and 32 are formed on the first signal wiring layer 12 and the third signal wiring layer 20, respectively, which are the outer layers of the multilayer printed board 10. In addition, a signal wiring pattern 23 and a ground pattern 24 for shielding noise caused by the signal wiring pattern 23 are formed on the second signal wiring layer 14 which is the inner layer of the multilayer printed board 10.

Further, a ground plane 26 is formed on the ground layer 16 which is the inner layer of the multilayer printed board 10, and a power pattern 28 and a ground pattern 30 for shielding noise caused by the power pattern 28 are formed on the power layer 18.

There is a through hole 34 formed through the multilayer printed board 10. The inner wall of the through hole 34 is coated with a conducting layer 33 made of copper or the like, and the conducting layer 33, the ground pattern 22 and the ground pattern 32 are connected electrically.

Around the through hole 34 there are via holes 36, whose diameter is smaller than that of the through hole 34, formed through the multilayer printed board 10. As shown in FIG. 1A, the via holes 36 are four holes formed at predetermined intervals around the through hole 34. As shown in FIG. B, the inner wall of each of the via holes 36 is coated with a conducting layer 38 of copper or the like. The conducting layer 38, the ground pattern 22, the ground pattern 24, the ground plane 26, the ground pattern 30 and the ground pattern 32 are connected electrically.

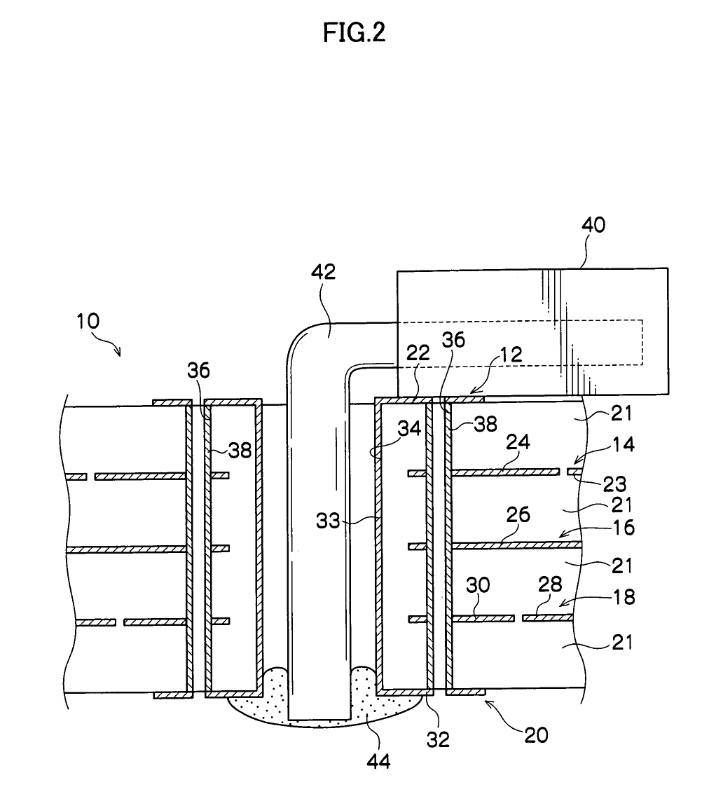

As shown in FIG. 2, the multilayer printed board 10 is configured to have a connector 40 mounted thereon. A ground pin 42 of the connector 40 is inserted through the through hole 34 and the distal end of the ground pin 42 is soldered to the ground pattern 32. The ground pin 42 is electrically connected to the ground pattern 32 by the solder 44. The ground pin 42 is electrically connected to the ground pattern 22 by the through hole 34 and the via holes 36 and is electrically connected to the ground pattern 24, the ground plane 26 and the ground pattern 30 by the via holes 36.

Next, an action of the embodiment of the present invention will be described.

As shown in FIG. 2, the multilayer printed board 10 is configured to have, for example, a connector 40 as an electronic component mounted on the surface thereof (the first signal wiring layer 12). The connector 40 is mounted on the multilayer printed board 10 by inserting the ground pin 42 into the through hole 34 formed through the multilayer printed board 10 and soldering the ground pin 42 thereto from the back surface.

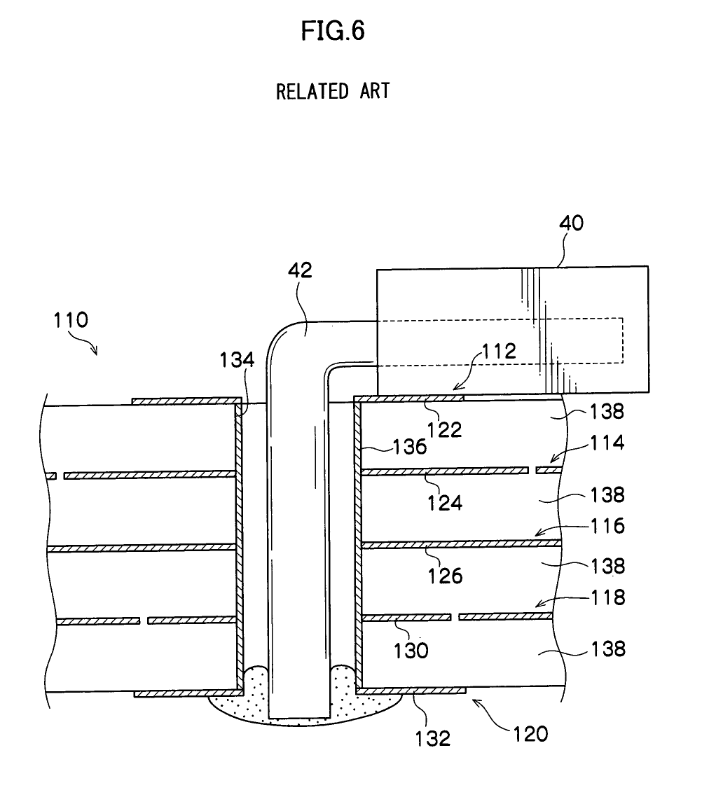

At this time, as shown in FIG. 6, if not only a ground pattern 122 and a ground pattern 132 formed on a first signal wiring layer 112 and a third signal wiring layer 120, respectively, of the both sides of a multilayer printed board 110, but also a ground pattern 124, a ground plane 126 and a ground pattern 130 formed on a second signal wiring layer 114, a ground layer 116 and a power layer 118, respectively, are connected to a conducting layer 136 coating the inner wall of a through hole 134, when a connector 40 is mounted on the multilayer printed board 110, heat applied to a ground pin 42 is dissipated from the ground pattern 124, the ground plane 126 and the ground pattern 130 via the conducting layer 136 into insulating layers 138. Namely, the ground pattern 124, the ground plane 126 and the ground pattern 130 serve as heat dissipating fins, which deteriorate heating performance of the ground pin 42 thereby making it difficult to fix the solder 44 to the ground pin 42.

Now, as shown in FIGS. 1 and 2, the ground pattern 22 and the ground pattern 32 formed on the first signal wiring layer 12 and the third signal wiring layer 20, respectively, of the outer layers of the multilayer printed board 10 are electrically connected by the conducting layer 33 coating the inner wall of the through hole 34. The ground pattern 24, the ground plane 26 and the ground pattern 30 formed on the second signal wiring layer 14, the ground layer 16 and the power layer 18, respectively, of the inner layers of the multilayer printed board 10 are electrically connected by the conducting layer 38 coating the inner walls of the via holes 36 formed around the through hole 34.

Namely, only the ground pattern 22 and the ground pattern 32 formed on the outer layers of the multilayer printed board 10 are connected to the conducting layer 33, and the ground pattern 24, the ground plane 26 and the ground pattern 30 formed on the inner layers of the multilayer printed board 10 are not connected to the conducting layer 33.

With this configuration, when the ground pin 42 of the connector 40 is inserted into the through hole 34 and soldered, heat applied to the ground pin 42 is prevented from being dissipated from the conducting layer 33 into the insulating layers 21 via the ground pattern 24, the ground plane 26 and the ground pattern 30 formed on the inner layers of the multilayer printed board 10. Accordingly, the heat performance of the ground pin 42 is improved with no possibility of causing poor soldering.

Here in the present embodiment, all the patterns of the inner layers of the multilayer printed board 10 (the ground pattern 24, the ground plane 26 and the ground pattern 30) are not connected to the conducting layer 33. In comparison with the case where all the patterns of the inner layers are connected to the conducting layer 136 as shown in FIG. 6, as the present invention is configured such that at least one of the patterns of the inner layers is not connected to the conducting layer 33, it is possible to achieve an effect of preventing heat applied to the ground pin 42 from being dissipated.

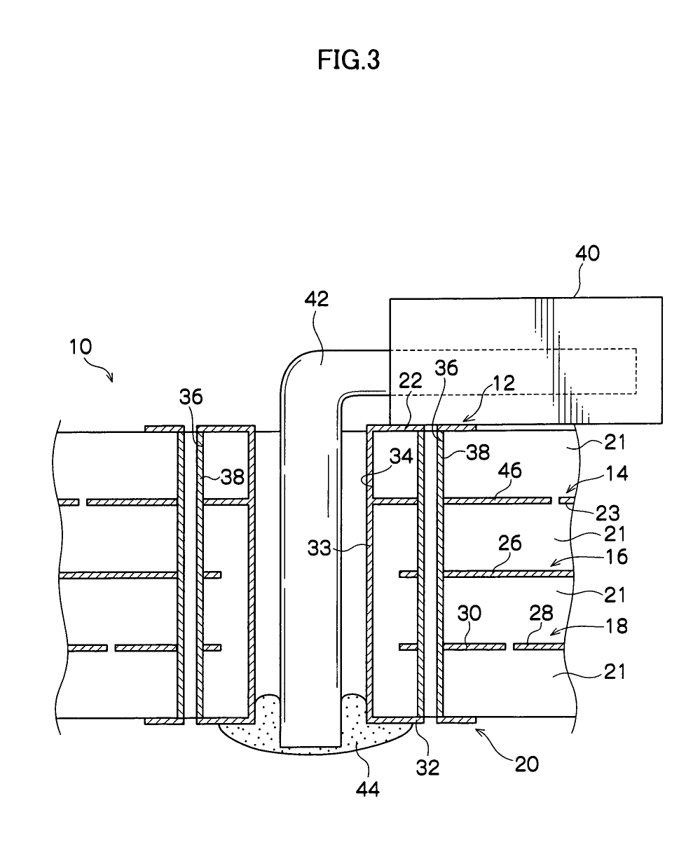

Particularly, as shown in FIG. 3, the ground pattern 46 far from the distal end of the ground pin 42 is connected to the conducting layer 33, and the ground plane 26 and the ground pattern 30 relatively near to the distal end of the ground pin 42 are not connected to the conducting layer 33. Such a configuration makes it easy to achieve the effect of preventing heat applied to the ground pin 42 from being dissipated.

In addition, if a new ground pattern is added by design change, the ground pattern is not connected to the conducting layer 33 but connected to the conducting layer 38 of the via holes 36. With this connection, the newly added ground pattern is connected to the other patterns electrically. Besides, heat applied to the ground pin 42 inserted into the through hole 34 is prevented from being dissipated into the insulating layers 21 from the conducting layer 33 via the ground patterns.

Further, as shown in FIG. 6, if the inner wall of the through hole 134 is coated with the conducting layer 136, even if the ground pattern 124, the ground plane 126 and the ground pattern 130 are not connected to the through hole 134, when heat is applied to the ground pin 42 inserted into the through hole 134, the heat of the ground pin 42 is dissipated into the insulating layers 138 via the conducting layer 136.

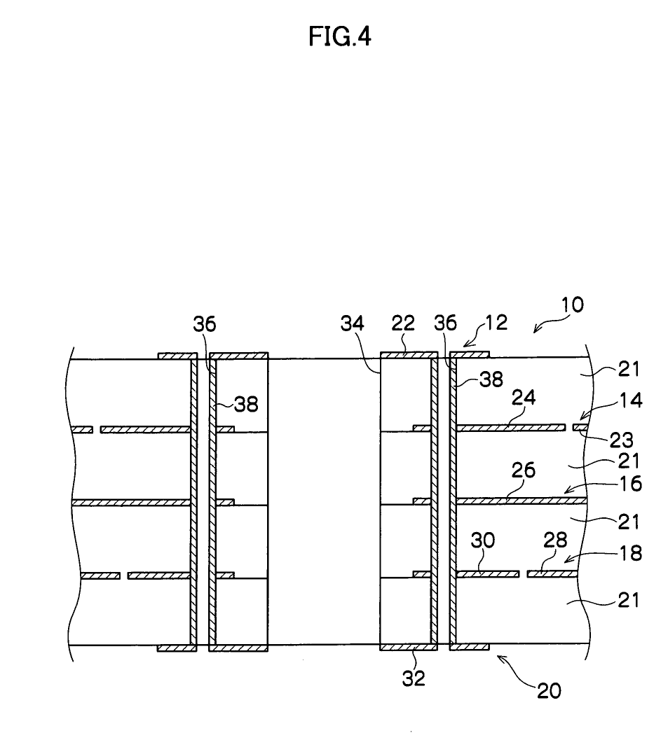

Then, as shown in FIG. 4, when the conducting layer is not provided on the inner wall of the through hole 34 and the insulating layer 21 is made bare, the heat applied to the ground pin 42 (see FIG. 2) is not dissipated into the insulating layers 138 thereby to improve heating performance of the ground pin 42.

Further, the present embodiment is described with the multilayer printed board 10 of five layers taken as an example. However, the printed board is not limited to the five-layer configuration and the present invention can be applied to a multilayer printed board of four layers or six layers.

Furthermore, the present embodiment is described, with use of the example of the through hole 34 into which the ground pin 42 of the connector 40 is inserted, based on the relation between the conducting layer 33 coating the inner wall of the through hole 34 and the ground patterns and the ground plane. However, not only in the through hole into which the ground pin 42 is inserted, but also in a through hole into which a power pin is inserted to be electrically connected to a power pattern of each layer and a through hole into which a signal pin is inserted to be electrically connected to a signal pattern of each layer, it is possible to prevent the heat applied to the pin inserted into the through hole from being dissipated into the insulating layers by not connecting the patterns to the conducting layer coating the through hole.

Furthermore, this embodiment is configured to have four via holes 36 formed at predetermined intervals around the through hole 34. However, the number of the via holes 36 is not limited to four. The more the number of the layers of the multilayer printed board 10 or the more the total number of patterns becomes, the more current passes through the multilayer printed board 10. A larger current is allowed to pass through the multilayer printed board 10 by increasing the number of via holes 36 in proportion to the number of layers and the number of patterns even if the area of the conducting layer is not increased by enlarging the inner diameter of a via hole 36. Therefore, there is no possibility of upsizing the multilayer printed board 10.

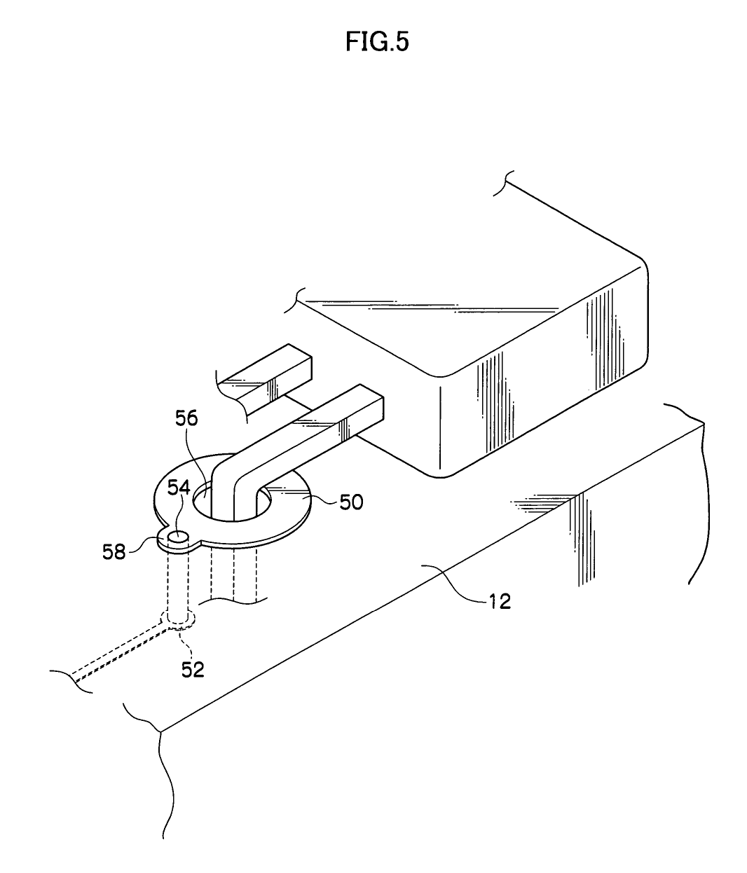

Furthermore, according to this embodiment, as shown in FIG. 1, the via holes 36 are formed to fall within the ground pattern 22 formed on the first signal wiring layer 12. However, as shown in FIG. 5, when a pad 50 formed on the first signal wiring layer 12 of the outer layer and the signal wiring pattern 52 formed on the second signal wiring layer 14 (see FIG. 1) are connected by the conducting layer coating the inner wall of the via hole 54, the signal wiring pattern 52 and the pad 50 may be connected electrically by forming a protruding portion 58 at the outer periphery of the pad 50 and forming a via hole 54 in the protruding portion 58. With this configuration, the pad 50 does not need to be enlarged more than necessary and therefore, there is no need to reduce the area for the pattern of the first signal wiring layer 12 to be formed. Accordingly, there is no need to upsize the multilayer printed board in order to form a necessary number of patterns.

The above-described configuration is adopted in the manufacturing steps of an electronic board in which electronic components are mounted on a multilayer printed board or an electronic device on which this electronic board is loaded. Then, in soldering a terminal of an electronic component to the multilayer printed board, heat applied to the terminal is prevented from being dissipated into insulating layers via a wiring pattern of the inner layer. Accordingly, the heating performance of the terminal is improved and there is no possibility of causing poor soldering.

Embodiments of the present invention are described above, but the present invention is not limited to the embodiments as will be clear to those skilled in the art. Namely, a first aspect of the present invention is a printed board having wiring patterns laminated with insulating layers therebetween, including: a through hole into which a terminal of an electronic component can be inserted and at which a conducting layer for connecting wiring patterns of outer layers is formed; a wiring pattern of an inner layer which is not connected electrically to the conducting layer; and via holes, provided around the through hole, for connecting the wiring pattern of the inner layer and the wiring patterns of the outer layers electrically.

According to the first aspect of the present invention, the wiring pattern of the inner layer is not connected to the wiring patterns of the outer layers via the conducting layer of the through hole, but is electrically connected to the wiring patterns of the outer layers by the via holes.

In other words, the wiring pattern of the inner layer is not connected to the through hole into which the terminal is inserted. With this configuration, when the electronic component is mounted on the printed board, or when the terminal of the electronic component is inserted into the through hole and soldered, heat applied to the terminal is prevented from being dissipated from the conducting layer into the insulating layers between the wiring patterns via the wiring pattern of the inner layer. Thus, heating performance of the terminal is improved without possibility of causing poor soldering.

The above-described configuration of the present invention allows prevention of poor soldering due to dissipating of heat applied to the terminal of the electronic component, such as a connector, when the electronic component is mounted on the printed board. In the first aspect of the present invention, the wiring pattern of the inner layer may be a wiring pattern of an inner layer closest to a wiring pattern of an outer layer to which the terminal is soldered.

In the above-mentioned configuration, the wiring pattern of the inner layer closest to the wiring pattern of the outer layer to which the terminal is soldered is not connected to the conducting layer of the through hole electrically, and is connected to the wiring patterns of the outer layers by the via holes.

Accordingly, in mounting an electronic component on the printed board, heat applied to the terminal is prevented from being dissipated into the insulating layers from the wiring pattern of the inner layer closest to the wiring pattern of the outer layer, thus, the heating performance of the distal end of the terminal to be soldered is not deteriorated.

In the first aspect of the present invention, none of the wiring patterns of the inner layers may be connected to the conducting layer and the wiring patterns may be connected to each other by the via holes.

In the above-described configuration, since none of wiring patterns of the inner layers are connected to the conducting layer, heat applied to the terminal is not dissipated into the insulating layers from the wiring patterns of the inner layers via the conducting layer. Accordingly, the heating performance of the terminal is improved. Here, the wiring patterns of the inner layers are configured to be connected to each other by the via holes so that a current can pass therebetween.

In the first aspect of the present invention, the conducting layer may not be formed at the through hole and the wiring patterns of the outer layers and inner layers may be connected by the via holes.

If the conducting layer is provided at the through hole, even if the wiring patterns of the inner layers are not connected to the conducting layer, heat applied to the terminal is possibly dissipated into the insulating layers via the conducting layer. In the above configuration, since the conducting layer is not provided at the through hole, heat applied to the terminal can be prevented from being dissipated into the insulating layers.

In the first aspect of the present invention, a number of the via holes may be increased in proportion to a number of laminated layers of the wiring patterns of the inner layers.

As the number of laminated layers of the inner layer wiring patterns is increased, a current passing through the printed board is also increased. In the above configuration, the number of the via holes are increased in proportion to the number of laminated layers of the inner layer wiring patterns so that a larger current is made to pass through the printed board without enlarging the inner diameter of the via hole to enlarge the area of the conducting layer. Therefore, there is no need to upsize the multilayer printed board due to an increase of the number of laminated layers.

In the first aspect of the present invention, the number of the via holes may be increased in proportion to the current flowing through the wiring patterns.

With this configuration, by increasing the number of the via holes in proportion to the size of a current passing through the wiring patterns, it becomes possible to make a large current pass through the printed board without enlarging the inner diameter of the via hole to enlarge the area of the conducting layer.

In the first aspect of the present invention, a protruding portion may be formed at a part of a pad provided at at least one of the wiring patterns of the outer layers and may be connected to the via hole.

In this configuration, the protruding portion partially protruding from the pad provided at the outer layer is connected to the via hole, thus, it is possible to eliminate the need to enlarge the pad on the outer layer more than necessary in corresponding to the positions of the wiring patterns. Since this configuration does not reduce the area of the outer layer on which the wiring pattern is formable, there is no need to upsize the printed board in order to form a necessary number of wiring patterns.

Further, a second aspect of the present invention is an electronic board including a printed board having wiring patterns laminated with insulating layers therebetween. The electronic board has a through hole into which a terminal of an electronic component can be inserted and at which a conducting layer for connecting wiring patterns of outer layers is formed; a wiring pattern of an inner layer which is not connected electrically to the conducting layer; and via holes, provided around the through hole, for connecting the wiring pattern of the inner layer and the wiring patterns of the outer layers electrically; and an electronic component mounted on the printed board.

According to the second aspect of the present invention, in manufacturing an electronic board composed of a printed board and electronic component mounted on this printed board, at the step of mounting the electronic component on the printed board, when a terminal of the electronic device is soldered to the printed board, heat applied to the terminal is prevented from being dissipated into the insulating layers via the wiring pattern of the inner layer. Accordingly, the heating performance of the terminal is improved and there is no possibility of causing poor soldering.

Further, a third aspect of the present invention is an electronic device including an electronic board which is loaded within the electronic device and has a printed board having wiring patterns laminated with insulating layers therebetween. The printed board has a through hole into which a terminal of an electronic component can be inserted and at which a conducting layer for connecting wiring patterns of outer layers is formed; a wiring pattern of an inner layer which is not connected electrically to the conducting layer; and via holes, provided around the through hole, for connecting the wiring pattern of the inner layer and the wiring patterns of the outer layers electrically; and an electronic component mounted on the printed board.

According to the third aspect of the present invention, at the step of mounting the electronic component on the printed board which constitutes the electronic board, when a terminal of the electronic component is soldered to the printed board, heat applied to the terminal is prevented from being dissipated into the insulating layers via the wiring pattern of the inner layer. Accordingly, the heating performance of the terminal is improved and there is no possibility of causing poor soldering.

What is claimed is:

1. A printed board having wiring patterns laminated with insulating layers therebetween, comprising:
a through hole into which a terminal of an electronic component can be inserted and at which a conducting layer for connecting wiring patterns of outer layers is formed;
a wiring pattern of an inner layer which is not connected electrically to the conducting layer; and
via holes, provided around the through hole, for connecting the wiring pattern of the inner layer and the wiring patterns of the outer layers electrically.

2. The printed board of claim 1, further comprising a plurality of inner layers, wherein the wiring pattern of the inner layer is a wiring pattern of an inner layer which is closest to a wiring pattern of an outer layer to which the terminal is soldered.

3. The printed board of claim 1, further comprising a plurality of inner layers, wherein none of wiring patterns of the plurality of inner layers are connected to the conducting layer and the wiring patterns are connected to each other via the via holes.

4. The printed board of claim 1, wherein the conducting layer is not formed at the through hole and the wiring pattern of the inner layer and the wiring patterns of the outer layers are connected by the via holes.

5. The printed board of claim 1, wherein a number of the via holes is increased in proportion to a number of laminated layers of the wiring patterns of the inner layers.

6. The printed board of claim 1, wherein the via holes is increased in proportion to the size of a current passing through the wiring patterns.

7. The printed board of claim 1, wherein a protruding portion is formed at a part of a pad provided at at least one of the wiring patterns of the outer layers and the via holes are connected to the protruding portion.

8. An electronic board comprising:
a printed board having wiring patterns laminated with insulating layers therebetween, comprising
a through hole into which a terminal of an electronic component can be inserted and at which a conducting layer for connecting wiring patterns of outer layers is formed;
a wiring pattern of an inner layer which is not connected electrically to the conducting layer; and
via holes, provided around the through hole, for connecting the wiring pattern of the inner layer and the wiring patterns of the outer layers electrically; and
an electronic component mounted on the printed board.

9. The electronic board of claim 8, wherein the printed board further comprises a plurality of inner layers, wherein the wiring pattern of the inner layer is a wiring pattern of an inner layer which is closest to a wiring pattern of an outer layer to which the terminal is soldered.

10. The electronic board of claim 8, wherein the printed board further comprises a plurality of inner layers, wherein none of wiring patterns of the plurality of inner layers are connected to the conducting layer and the wiring patterns are connected to each other via the via holes.

11. The electronic board of claim 8, wherein the conducting layer is not formed at the through hole and the wiring pattern of the inner layer and the wiring patterns of the outer layers are connected by the via holes.

12. The electronic board of claim 8, wherein a number of the via holes is increased in proportion to a number of laminated layers of the wiring patterns of the inner layers.

13. The electronic board of claim 8, wherein the number of the via holes is increased in proportion to the size of a current passing through the wiring patterns.

14. The electronic board of claim 8, wherein a protruding portion is formed at a part of a pad provided at at least one of the wiring patterns of the outer layers and the via holes are connected to the protruding portion.

15. An electronic device comprising:
an electronic board loaded within the electronic device and comprising
a printed board having wiring patterns laminated with insulating layers therebetween, comprising
a through hole into which a terminal of an electronic component can be inserted and at which a conducting layer for connecting wiring patterns of outer layers is formed;
a wiring pattern of an inner layer which is not connected electrically to the conducting layer; and
via holes, provided around the through hole, for connecting the wiring pattern of the inner layer and the wiring patterns of the outer layers electrically; and
an electronic component mounted on the printed board.

16. The electronic device of claim 15, wherein the printed board further comprises a plurality of inner layers, wherein the wiring pattern of the inner layer is a wiring pattern of an inner layer which is closest to a wiring pattern of an outer layer to which the terminal is soldered.

17. The electronic device of claim 15, wherein the printed board further comprises a plurality of inner layers, wherein none of wiring patterns of the plurality of inner layers are connected to the conducting layer and the wiring patterns are connected to each other via the via holes.

18. The electronic device of claim 15, wherein the conducting layer is not formed at the through hole and the wiring pattern of the inner layer and the wiring patterns of the outer layers are connected by the via holes.

19. The electronic device of claim 15, wherein a number of the via holes are increased in proportion to a number of laminated layers of the wiring patterns of the inner layers.

20. The electronic device of claim 15, wherein a number of the via holes are increased in proportion to the size of a current passing through the wiring patterns.
